(19) United States
(12) Patent Application Publication
(10) Pub. No.: US 2026/0129913 A1
(43) Pub. Date: May 7, 2026

(54) OXIDE SEMICONDUCTOR THIN-FILM TRANSISTOR

(71) Applicant: Tianma Japan, Ltd., Kanagawa (JP)

(72) Inventors: Hiroyuki SEKINE, Kanagawa (JP); Shigeru KIMURA, Kanagawa (JP)

(21) Appl. No.: 19/379,476

(22) Filed: Nov. 4, 2025

(30) Foreign Application Priority Data
Nov. 6, 2024 (JP) 2024-194387

(51) Int. Cl. H10D 30/67

(52) U.S. Cl. CPC H10D 30/6755; H10D 30/6732; H10D 30/6736; H10D 30/6739

(57) ABSTRACT

An oxide semiconductor thin-film transistor includes a gate electrode, a source electrode, a drain electrode, an oxide semiconductor layer connected to the source electrode and the drain electrode, and a gate insulating film between the gate electrode and the oxide semiconductor layer in a layering direction. The oxide semiconductor layer includes a channel region. The gate insulating film includes a metal oxide film and a first insulating film made of silicon nitride and/or silicon oxynitride. A part of the first insulating film is disposed between the metal oxide film and the oxide semiconductor layer. At least a part of a first end of the metal oxide film lies on the channel region and faces either one of the source electrode and the drain electrode in a planar view.

### CROSS-REFERENCE TO RELATED APPLICATIONS

This non-provisional application claims priority under 35 U.S.C. § 119(a) on Patent Application No. 2024-194387 filed in Japan on Nov. 6, 2024, the entire content of which is hereby incorporated by reference.

### BACKGROUND

This disclosure relates to oxide semiconductor thin-film transistors.

Thin-film transistors (TFTs) are used in various fields such as display devices and radiation sensors. A TFT having an active layer made of an oxide semiconductor represented by InGaZnO (IGZO) attains high mobility, despite its amorphous structure. However, controlling its threshold voltage is difficult because the added donors and acceptors make it difficult to control the Fermi energy.

### SUMMARY

An oxide semiconductor thin-film transistor according to an aspect of this disclosure includes a gate electrode, a source electrode, a drain electrode, an oxide semiconductor layer connected to the source electrode and the drain electrode, and a gate insulating film between the gate electrode and the oxide semiconductor layer in a layering direction. The oxide semiconductor layer includes a channel region. The gate insulating film includes a metal oxide film and a first insulating film made of silicon nitride and/or silicon oxynitride. A part of the first insulating film is disposed between the metal oxide film and the oxide semiconductor layer. At least a part of a first end of the metal oxide film lies on the channel region and faces either one of the source electrode and the drain electrode in a planar view.

It is to be understood that both the foregoing general description and the following detailed description are exemplary and explanatory and are not restrictive of this disclosure.

### BRIEF DESCRIPTION OF THE DRAWINGS

FIG. 1 illustrates an X-ray sensor.

FIG. 2 illustrates a cross-sectional structure of a pixel of an X-ray sensor.

FIG. 3 is a cross-sectional diagram schematically illustrating a configuration example of an oxide semiconductor TFT having a gate insulating film made of a layered SiNx/SiOx/SiNx film.

FIG. 4A is a band diagram for illustrating the movement of carriers when an oxide semiconductor TFT is being irradiated with X-rays.

FIG. 4B is another band diagram for illustrating the movement of carriers when an oxide semiconductor TFT is being irradiated with X-rays.

FIG. 5 is a cross-sectional diagram schematically illustrating the configuration of an oxide semiconductor TFT in an embodiment of this disclosure.

FIG. 6 is a plan diagram schematically illustrating positional relations among the silicon oxide film, the channel region, and some other components in an oxide semiconductor TFT.

FIG. 7A schematically illustrates a charge state occurring when the oxide semiconductor TFT in the embodiment illustrated in FIGS. 5 and 6 is supplied with a gate bias and irradiated with radioactive rays.

FIG. 7B is a graph schematically illustrating the negative shift of the threshold voltage.

FIG. 8A schematically illustrates another charge state occurring when the oxide semiconductor TFT in the embodiment illustrated in FIGS. 5 and 6 is supplied with a gate bias and irradiated with radioactive rays.

FIG. 8B is a graph schematically illustrating the positive shift of the threshold voltage.

FIG. 9 provides a graph illustrating the relations between the intensity of electric fields generated by planar charges having different areas and the distance from the planar charges.

FIG. 10 is a cross-sectional diagram schematically illustrating the configuration of an oxide semiconductor TFT in another embodiment of this disclosure.

FIG. 11 is a plan diagram schematically illustrating the positional relations among the silicon oxide film, the channel region, and some other components in the oxide semiconductor TFT illustrated in FIG. 10.

FIG. 12 is a cross-sectional diagram schematically illustrating the configuration of an oxide semiconductor TFT in still another embodiment of this disclosure.

FIG. 13 is a plan diagram schematically illustrating the positional relations among the silicon oxide film, the channel region, and some other components in the oxide semiconductor TFT illustrated in FIG. 12.

FIG. 14A illustrates a planar charge infinitely spreading in both positive and negative directions along the Y-axis and the positive direction along the X-axis.

FIG. 14B indicates the intensity of the Z-axis component of the electric field generated by the planar charge in FIG. 14A at different coordinates (x, z).

FIG. 15 is a cross-sectional diagram schematically illustrating the configuration of an oxide semiconductor TFT in still another embodiment of this disclosure.

FIG. 16 is a plan diagram schematically illustrating the positional relations among the silicon oxide film, the channel region, and some other components in the oxide semiconductor TFT illustrated in FIG. 15.

FIG. 17 is a plan diagram schematically illustrating the configuration of an oxide semiconductor TFT in still another embodiment of this disclosure.

FIG. 18 is a cross-sectional diagram schematically illustrating the configuration of an oxide semiconductor TFT in still another embodiment of this disclosure.

FIG. 19 is a cross-sectional diagram schematically illustrating the configuration of an oxide semiconductor TFT in still another embodiment of this disclosure.

FIG. 20A illustrates a step in a method of manufacturing an oxide semiconductor TFT.

FIG. 20B illustrates a step in the method of manufacturing an oxide semiconductor TFT.

FIG. 20C illustrates a step in the method of manufacturing an oxide semiconductor TFT.

FIG. 20D illustrates a step in the method of manufacturing an oxide semiconductor TFT.

FIG. 20E illustrates a step in the method of manufacturing an oxide semiconductor TFT.

FIG. 20F illustrates a step in the method of manufacturing an oxide semiconductor TFT.

FIG. 20G illustrates a step in the method of manufacturing an oxide semiconductor TFT.

FIG. 20H illustrates a step in the method of manufacturing an oxide semiconductor TFT.

FIG. 20I illustrates a step in the method of manufacturing an oxide semiconductor TFT.

FIG. 20J illustrates a step in the method of manufacturing an oxide semiconductor TFT.

FIG. 21A illustrates a step in another method of manufacturing an oxide semiconductor TFT.

FIG. 21B illustrates a step in the other method of manufacturing an oxide semiconductor TFT.

FIG. 21C illustrates a step in the other method of manufacturing an oxide semiconductor TFT.

FIG. 21D illustrates a step in the other method of manufacturing an oxide semiconductor TFT.

FIG. 21E illustrates a step in the other method of manufacturing an oxide semiconductor TFT.

FIG. 21F illustrates a step in the other method of manufacturing an oxide semiconductor TFT.

FIG. 21G illustrates a step in the other method of manufacturing an oxide semiconductor TFT.

FIG. 21H illustrates a step in the other method of manufacturing an oxide semiconductor TFT.

FIG. 21I illustrates a step in the other method of manufacturing an oxide semiconductor TFT.

FIG. 21J illustrates a step in the other method of manufacturing an oxide semiconductor TFT.

### EMBODIMENTS

Hereinafter, embodiments are described with reference to the accompanying drawings. The embodiments are merely examples to implement this disclosure and they are not to limit the technical scope of this disclosure. Some elements in the drawings may be exaggerated in size or shape for clear understanding of the description.

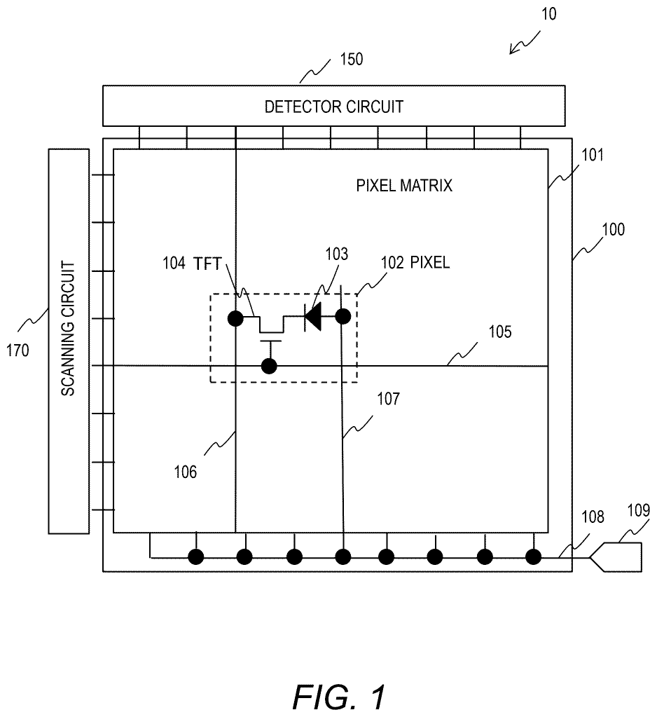

The oxide semiconductor thin-film transistors (TFTs) in the embodiments of this disclosure are applicable to various devices such as display devices and radiation sensors. FIG. 1 illustrates an X-ray sensor 10 as an example of a device that can employ the oxide semiconductor TFTs according to the embodiments of this disclosure. For example, the X-ray sensor 10 is an image sensor for imaging X-rays transmitted through an object.

The X-ray sensor 10 includes a pixel matrix 101, a scanning circuit 170, and a detector circuit 150. The pixel matrix 101 includes pixels 102 arrayed in a matrix. The pixel matrix 101 is fabricated on a substrate 100. The substrate 100 is an insulating substrate (e.g., a glass substrate or a resin substrate).

The pixels 102 are disposed at intersections between a plurality of signal lines 106 and a plurality of gate lines (scanning lines) 105. In FIG. 1, the signal lines 106 are disposed to extend vertically and be horizontally distant from one another and the gate lines 105 are disposed to extend horizontally and be vertically distant from one another. Each pixel 102 is connected to a bias line 107. In FIG. 1, a plurality of bias lines 107 are disposed to extend vertically and be horizontally distant from one another. In FIG. 1, only one of the pixels, one of the signal lines, one of the gate lines, and one of the bias lines are provided with reference signs 102, 106, 105, and 107, respectively.

Each signal line 106 is connected to a different pixel column. Each gate line 105 is connected to a different pixel row. The signal line 106 is connected to the detector circuit 150 and the gate line 105 is connected to the scanning circuit 170. Each bias line 107 is connected to a common bias line 108. A bias potential is supplied to a pad 109 of the common bias line 108.

Each pixel 102 includes a photodiode 103 of a photoelectric conversion element and a TFT 104 of a switching element. In the TFT 104, the gate is connected to a gate line 105; one source/drain is connected to a signal line 106; and the other source/drain is connected to the cathode of the photodiode 103. In the example of FIG. 1, the anode of the photodiode 103 is connected to a bias line 107.

The TFT 104 in the configuration example of FIG. 1 has an n-type of conductivity. The TFT 104 can have a different conductivity. In this embodiment, the TFT 104 is an oxide semiconductor TFT. The oxide semiconductor TFT exhibits a good switching characteristic.

The X-ray sensor 10 reads a signal of a pixel 102 by taking out signal charge stored in a photodiode 103 in proportion to the amount of X-ray irradiation from the photodiode 103 to the external. The signal charge can be taken out by making the TFT 104 in the pixel 102 conductive. Specifically, when light enters the photodiode 103, signal charge is generated and stored in the photodiode 103.

The scanning circuit 170 selects the gate lines 105 one by one to apply a pulse to make the TFT 104 conductive. The anode terminal of the photodiode 103 is connected to a bias line 107 and the signal line 106 is supplied with a reference potential by the detector circuit 150. Accordingly, the photodiode 103 is charged with a difference voltage between the bias potential of the bias line 107 and the reference potential. This difference voltage is determined so that the cathode potential is higher than the anode potential to reverse-bias the photodiode 103.

The charge required to recharge the photodiode 103 to the reverse bias voltage depends on the amount of light incident on the photodiode 103. The detector circuit 150 reads the signal charge by integrating the current that flows until the photodiode 103 is recharged to the reverse bias voltage.

The charge stored in the photodiode 103 inevitably decreases because of incident light and dark leakage current that flows even when the photodiode 103 is not irradiated with light. Accordingly, in the TFT 104 under the operation of signal charge reading, the voltage at the terminal connected to the signal line 106 is equal to or higher than the voltage at the terminal connected to the photodiode 103. That is to say, the terminal connected to the signal line 106 is the drain and the terminal connected to the photodiode 103 is the source in detecting signal charge.

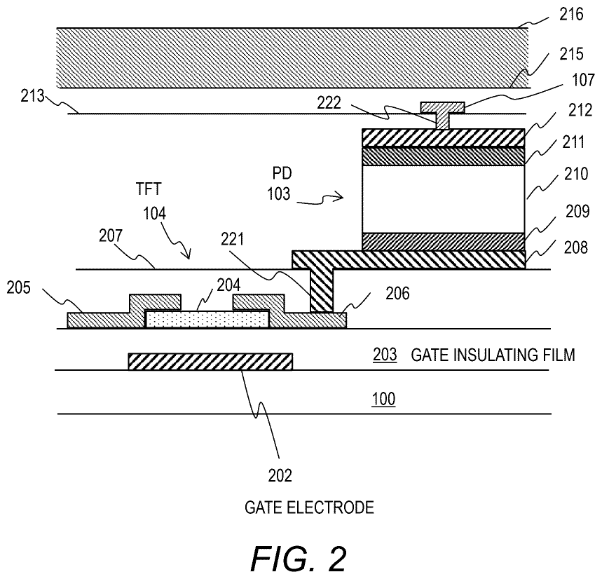

FIG. 2 illustrates a cross-sectional structure of a pixel. In the following description, the side where the test object is to be placed with respect to the X-ray sensor 10 is defined as front. In FIG. 2, the side opposite from the substrate 100 with respect to the photodiode 103 is the front. In the positional relations among the components of a pixel, the side closer to the substrate 100 is referred to as lower side and the opposite side as upper side.

The TFT 104 and the photodiode 103 included in a pixel each have a multilayer structure. The TFT 104 includes a gate electrode 202 provided above the substrate 100 having insulating properties, a gate insulating film 203 above the gate electrode 202, and an oxide semiconductor layer 204 above the gate insulating film 203. As will be described later, the gate insulating film 203 includes a plurality of layers of insulating films of different materials.

The TFT 104 in FIG. 2 has a bottom-gate structure; the gate electrode 202 is located under the oxide semiconductor layer 204. The TFT 104 further includes a source/drain electrode 205 and another source/drain electrode 206 above the gate insulating film 203. The source/drain electrodes 205 and 206 are individually connected to the oxide semiconductor layer 204. Each of the source/drain electrodes 205 and 206 is in contact with a side face and a part of the top face of the island-like oxide semiconductor layer 204.

One of the source/drain electrodes 205 and 206 is a source electrode and the other one is a drain electrode depending on the flow of the carriers. In detecting the charge of the photodiode 103, the electrode 205 is a drain electrode and the electrode 206 is a source electrode. Accordingly, the following description refers to the electrode 205 as drain electrode and the electrode 206 as source electrode.

The gate insulating film 203 is provided to cover the entire gate electrode 202. The gate insulating film 203 is provided between the gate electrode 202 and the oxide semiconductor layer 204, between the gate electrode 202 and the drain electrode 205, and between the gate electrode 202 and the source electrode 206.

A first interlayer insulating layer 207 is provided to cover the entire TFT 104. Specifically, the first interlayer insulating layer 207 covers the top face of the oxide semiconductor layer 204, the top face of the drain electrode 205, and the top face of the source electrode 206.

The substrate 100 can be made of glass or resin. The gate electrode 202 is a conductor and can be made of a metal or impurity-doped silicon. The gate insulating film 203 has a multilayer structure. The gate insulating film 203 can include an insulating film made of an oxide and another insulating film made of a nitride or an oxynitride. The specifics of the gate insulating film 203 will be described later.

The oxide semiconductor for the oxide semiconductor layer 204 is an oxide semiconductor including at least one of In, Ga, and Zn, such as amorphous InGaZnO (a-InGaZnO) or microcrystalline InGaZnO. Other oxide semiconductors such as a-InSnZnO and a-InGaZnSnO can also be employed. The examples described in the following principally employ amorphous or microcrystalline InGaZnO (which can also be expressed as IGZO in the following).

The drain electrode 205 and the source electrode 206 are conductors and can be made of a metal such as Mo, Ti, Al, or Cr, an alloy thereof, or a layered structure of these metals or alloys. The first interlayer insulating layer 207 is an inorganic or organic insulator. Although the TFT 104 in FIG. 2 has a bottom-gate structure, the TFT 104 can have a top-gate structure or a double-gate structure including both of a top gate and a bottom gate, instead.

The photodiode 103 is provided above the first interlayer insulating layer 207. The example of the photodiode 103 in FIG. 2 is a PIN diode. The PIN diode has a thick depletion layer in the film thickness to allow efficient light detection. The photodiode 103 includes layered semiconductors sandwiched between a lower electrode 208 above the first interlayer insulating layer 207 and an upper electrode 212. The lower electrode 208 is connected to the source electrode 206 of the TFT 104 through the interconnection region in a via hole 221 of the first interlayer insulating layer 207.

The lower electrode 208 is a conductor and can be made of a metal such as Cr, Mo, or Al, an alloy thereof, or a layered structure of these metals or alloys. The upper electrode 212 is a transparent electrode that transmits light from a scintillator 216 and can be made of ITO, for example.

The photodiode 103 includes an n-type amorphous silicon layer 209 above the lower electrode 208, an intrinsic amorphous silicon layer 210 above the n-type amorphous silicon layer 209, and a p-type amorphous silicon layer 211 above the intrinsic amorphous silicon layer 210. The upper electrode 212 is provided above the p-type amorphous silicon layer 211. The light to be detected enters the photodiode 103 from above the upper electrode 212 (the p-type amorphous silicon layer 211).

A second interlayer insulating layer 213 is provided to cover the photodiode 103. Specifically, the second interlayer insulating layer 213 is provided above a part of the first interlayer insulating layer 207 and the upper electrode 212. The second interlayer insulating layer 213 is an inorganic or organic insulator.

A bias line 107 is provided above the second interlayer insulating layer 213. The bias line 107 is connected to the upper electrode 212 through an interconnection region provided in a via hole 222 of the second interlayer insulating layer 213. The bias line 107 is a conductor and can be made of a metal such as Mo, Ti, or Al, an alloy thereof, or a layered structure of these metals or alloys.

A passivation layer 215 is provided to cover the bias line 107 and the second interlayer insulating layer 213. The passivation layer 215 covers the entire pixel matrix 101. The passivation layer 215 is an inorganic or organic insulator. A scintillator 216 is provided above the passivation layer 215.

The scintillator 216 covers the entire pixel matrix 101. The scintillator 216 emits light by being excited by radioactive rays. Specifically, the scintillator 216 converts the received X-rays into light having a wavelength detectable for the photodiode 103. The photodiode 103 stores signal charge in the amount depending on the light from the scintillator 216.

Hereinafter, the configuration of an oxide semiconductor TFT in an embodiment of this disclosure is described. The oxide semiconductor TFT in this embodiment is applicable to devices other than the above-described X-ray sensor, for example, display devices.

A TFT having an active layer made of an oxide semiconductor represented by InGaZnO (IGZO) attains high mobility, despite its amorphous structure. However, controlling its threshold voltage is difficult because the added donors and acceptors make it difficult to control the Fermi energy.

The inventors studied the way to control the threshold voltage of an oxide semiconductor TFT by configuring the gate insulating film of a layered SiNx/SiOx/SiNx film and irradiating the TFT in a state being supplied with a gate voltage with light having energy larger than the bandgap of the gate insulating film to make the interfaces of the aforementioned three layers store desired charges. The threshold voltage of the TFT can be controlled by controlling the potential at the interface of the oxide semiconductor with the electric fields generated by the charges (refer to U.S. application Ser. No. 18/781,161, the entire content of which is hereby incorporated by reference).

Specifically, when an oxide semiconductor is irradiated with X-rays of high-energy light, pairs of holes (h) and electrons (e) are photoexcited to be generated. When a negative voltage is applied between the source and the gate of a TFT, the holes in the oxide semiconductor hop to the interface with SiNx of the gate insulating film and trapped into the interface state to cause a threshold voltage shift. When a positive voltage is applied between the source and the gate, the electrons induced in the channel are trapped into the interface with SiNx of the gate insulating film to cause a threshold voltage shift.

These threshold voltage shifts can be reduced by configuring the gate insulating film to have a three-layer structure of SiNx/SiOx/SiNx. Different polarities of charges are separately collected to the two interfaces within the gate insulating film depending on the polarity of the voltage applied between the source and the gate to balance out the electric field generated by the charge trapped in the interface of the oxide semiconductor layer with the electric fields generated by the collected charges.

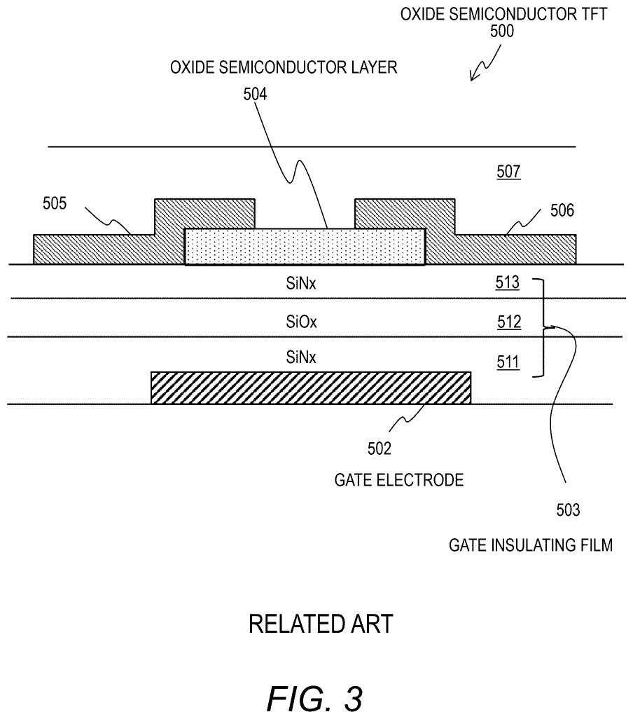

FIG. 3 is a cross-sectional diagram schematically illustrating a configuration example of an oxide semiconductor TFT having a gate insulating film made of a layered SiNx/SiOx/SiNx film. The oxide semiconductor TFT 500 includes a gate electrode 502, a gate insulating film 503 above the gate electrode 502, and an oxide semiconductor layer 504 above the gate insulating film 503. An interlayer insulating film 507 is provided to cover the entire oxide semiconductor TFT 500.

The gate insulating film 503 has a three-layer structure configured of a lower silicon nitride (SiNx) film 511, a silicon oxide (SiOx) film 512 above the lower silicon nitride film 511, and an upper silicon nitride film 513 above the silicon oxide film 512. These are the lower region, the middle region, and the upper region of the gate insulating film 503.

The silicon oxide film 512 of the middle insulating layer is in contact with the lower silicon nitride film 511 and the upper silicon nitride film 513 and has interfaces with them. In the gate insulating film 503, the lower silicon nitride film 511 has an interface with the gate electrode 502 and the upper silicon nitride film 513 has an interface with the oxide semiconductor layer 504.

The oxide semiconductor TFT 500 has a bottom-gate structure; the gate electrode 502 is located lower than the oxide semiconductor layer 504. The oxide semiconductor TFT 500 further includes source/drain electrodes 505 and 506 above the gate insulating film 503. Each of the source/drain electrodes 505 and 506 is connected to the oxide semiconductor layer 504.

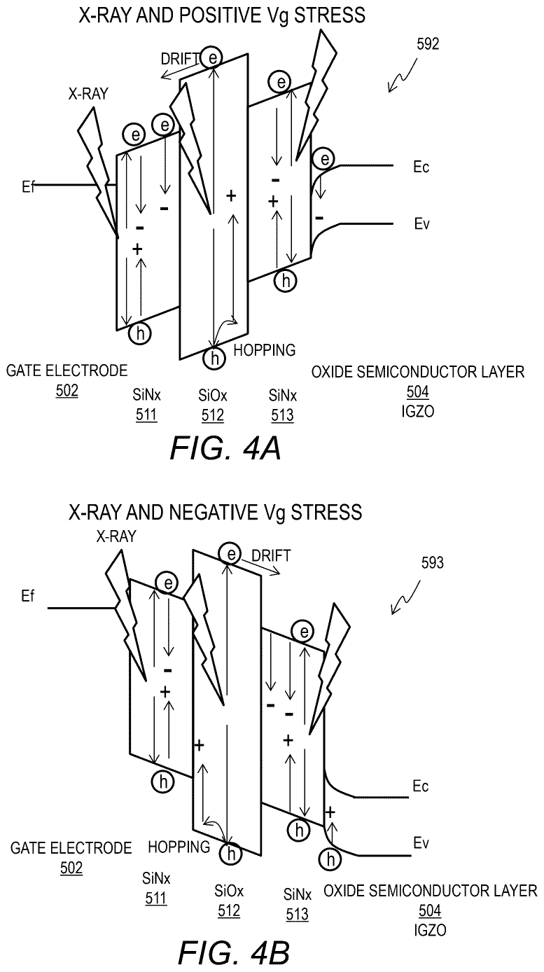

FIGS. 4A and 4B are band diagrams for illustrating the movement of carriers when an oxide semiconductor TFT is being irradiated with X-rays. The band diagram 592 in FIG. 4A illustrates electron energy levels of the gate electrode 502, the lower silicon nitride film 511, the silicon oxide film 512, the upper silicon nitride film 513, and the oxide semiconductor layer 504 when a positive gate voltage is applied to the oxide semiconductor TFT 500 being irradiated with X-rays. In the diagram, Ec represents the lower edge of the conduction band of the oxide semiconductor layer 504, the lower silicon nitride film 511, the silicon oxide film 512, and the upper silicon nitride film 513; Ev represents the upper edge of the valence band of the oxide semiconductor layer 504, the lower silicon nitride film 511, the silicon oxide film 512, and the upper silicon nitride film 513; and Ef represents the Fermi level of the gate electrode (metal layer) 502.

The electrons (e) generated by X-rays in the lower silicon nitride film 511 are trapped into the electron trap levels in the lower silicon nitride film 511. The holes (h) generated in the lower silicon nitride film 511 are trapped into the hole trap levels in the lower silicon nitride film 511.

In similar, the electrons (e) generated by X-rays in the upper silicon nitride film 513 are trapped into the electron trap levels in the upper silicon nitride film 513. The holes (h) generated in the upper silicon nitride film 513 are trapped into the hole trap levels in the upper silicon nitride film 513.

The electrons (e) generated by X-rays in the silicon oxide film 512 move to the lower silicon nitride film 511 having lower energy levels and are trapped into the electron trap levels in the lower silicon nitride film 511. The holes (h) generated in the silicon oxide film 512 are trapped into the hole trap levels in the silicon oxide film 512. As a result, a positive charge is stored in the vicinity of the interface between the silicon oxide film 512 and the upper silicon nitride film 513.

The electrons (e) generated by X-rays in the oxide semiconductor layer 504 move to the vicinity of the interface between the upper silicon nitride film 513 and the oxide semiconductor layer 504 because of the positive gate voltage and they are trapped there. The negative charge by the trapped electrons and the positive charge stored in the vicinity of the interface between the silicon oxide film 512 and the upper silicon nitride film 513 cancel each other to reduce the variation in potential of the oxide semiconductor layer 504, suppressing the shift in Vg-Id characteristic of the thin-film transistor 500.

The band diagram 593 in FIG. 4B illustrates electron energy levels of the gate electrode 502, the lower silicon nitride film 511, the silicon oxide film 512, the upper silicon nitride film 513, and the oxide semiconductor layer 504 when a negative gate voltage is applied to the oxide semiconductor TFT 500 being irradiated with X-rays. The reference signs Ec, Ev, and Ef and the band gaps of the silicon oxide, silicon nitride, and oxide semiconductor are the same as those in the band diagram 592.

The electrons (e) and holes (h) generated by X-rays in the lower silicon nitride film 511 are respectively trapped into the electron trap levels and the hole trap levels in the lower silicon nitride film 511.

In similar, the electrons (e) generated by X-rays in the upper silicon nitride film 513 are trapped into the electron trap levels in the upper silicon nitride film 513. The holes (h) generated in the upper silicon nitride film 513 are trapped into the hole trap levels in the upper silicon nitride film 513.

The electrons (e) generated by X-rays in the silicon oxide film 512 move to the upper silicon nitride film 513 having lower energy levels and are trapped into the electron trap levels in the upper silicon nitride film 513. As a result, a negative charge is stored in the vicinity of the interface between the silicon oxide film 512 and the upper silicon nitride film 513. The holes (h) generated in the silicon oxide film 512 are trapped into the hole trap levels in the silicon oxide film 512.

The holes (h) generated by X-rays in the oxide semiconductor layer 504 move to the vicinity of the interface between the upper silicon nitride film 513 and the oxide semiconductor layer 504 because of the negative gate voltage and they are trapped there. The positive charge by the trapped holes and the negative charge stored in the vicinity of the interface between the silicon oxide film 512 and the upper silicon nitride film 513 cancel each other to reduce the variation in potential of the oxide semiconductor layer 504, suppressing the shift in Vg-Id characteristic of the oxide semiconductor TFT 500.

Through the inventors'further study, a more effective approach to control the threshold voltage of the oxide semiconductor TFT was found. The approach is to reduce the area of the silicon oxide film in the multilayer gate insulating film that is away from the oxide semiconductor layer in the layering direction. As a result, the distance dependency of the intensity of the electric field generated by the trapped charge increases, attaining a larger difference in intensity between the electric field by the positive charge and the electric field by the negative charge at the position of the oxide semiconductor layer.

An embodiment of this disclosure makes a part (a first insulating film) of the gate insulating film in the oxide semiconductor TFT of silicon nitride and/or silicon oxynitride and embeds a small island-like (isolated) metal oxide film (insulating film) in the gate insulating film in such a manner to overlap the channel region in the layering direction. The metal oxide film can be made of silicon oxide and/or aluminum oxide, for example.

Charges are distributed on the interface between the metal oxide film and the silicon nitride or silicon oxynitride film. Accordingly, providing a metal oxide film having a small area generates planar charges having the small area. Then, the electric field generated by the charge located close to the oxide semiconductor layer and the electric field generated by the charge located far from the oxide semiconductor layer have a large difference in intensity.

To positively shift the threshold voltage, the control should apply a voltage between the source and the gate so that the charge near the oxide semiconductor layer will have a negative polarity (by applying a voltage negative with respect to the source potential to the gate) and irradiates the TFT with light having energy larger than the bandgap of the metal oxide film (e.g., X-rays). To negatively shift the threshold voltage, the control should apply a voltage positive with respect to the source potential to the gate and irradiates the TFT with the aforementioned high-energy light.

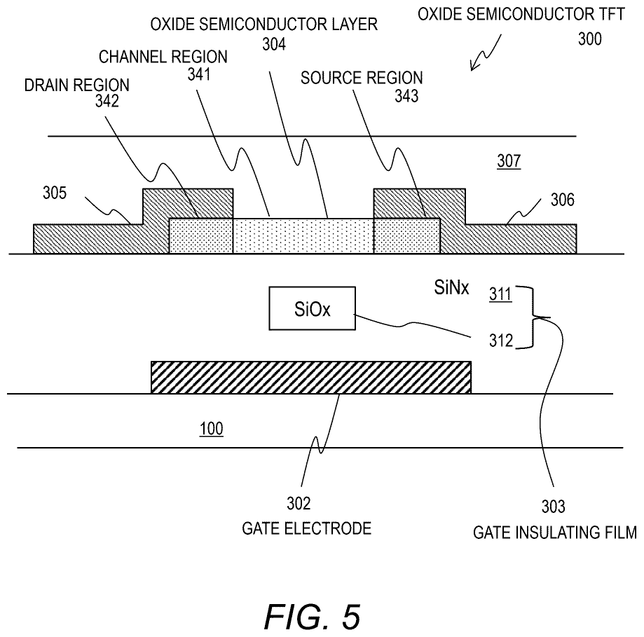

FIG. 5 is a cross-sectional diagram schematically illustrating the configuration of an oxide semiconductor TFT 300 in an embodiment of this disclosure. The oxide semiconductor TFT 300 can be used as the TFT 104 shown in FIGS. 1 and 2. Note that, for the components provided with the identical reference signs between FIGS. 2 and 5, the description provided with reference to FIG. 2 is applicable to the components in FIG. 5.

The oxide semiconductor TFT 300 includes a gate electrode 302, a gate insulating film 303 above the gate electrode 302, and an oxide semiconductor layer 304 above the gate insulating film 303. An interlayer insulating layer 307 is provided to cover the entire oxide semiconductor TFT 300.

The gate insulating film 303 has a multilayer structure and it consists of a silicon nitride (SiNx) film 311 and an isolated island-like silicon oxide (SiOx) film 312 embedded in the silicon nitride film 311. The silicon oxide film 312 is surrounded by the silicon nitride film 311 and its entire surface is in contact and has an interface with the silicon nitride film 311. A part of the silicon nitride film 311 is located between the silicon oxide film 312 and the oxide semiconductor layer 304 and the silicon oxide film 312 is away from the oxide semiconductor layer 304. Another part of the silicon nitride film 311 is located between the silicon oxide film 312 and the gate electrode 302 and the silicon oxide film 312 is away from the gate electrode 302.

The oxide semiconductor layer 304 includes a drain region 342, a source region 343, and a channel region 341 therebetween. The drain region 342 and the source region 343 have a lower resistance than the channel region 341. The drain region 342 and the source region 343 can be produced by reducing the resistance of the oxide semiconductor layer through exposure to hydrogen plasma or fluorine plasma. At least a part of the drain region 342 is in contact with a drain electrode 305. At least a part of the source region 343 is in contact with a source electrode 306.

The size of the channel region 341 can be defined by the channel width and the channel length. The channel length is the distance from the boundary between the source region 343 and the channel region 341 and the boundary between the drain region 342 and the channel region 341. The channel width is the dimension of the channel in the direction perpendicular to the channel length.

In a planar view of the configuration example of FIG. 5, the entire silicon oxide film 312 lies on the channel region 341; its area is smaller than the area of the channel region 341.

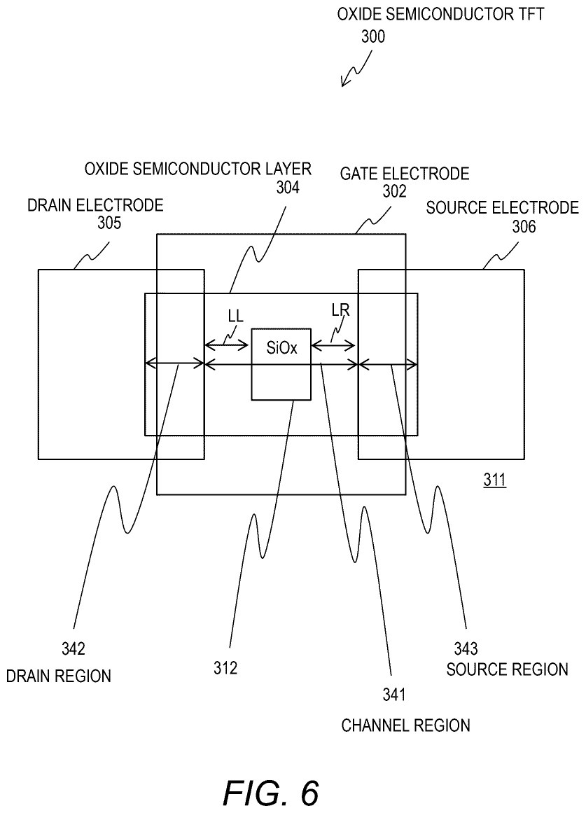

FIG. 6 is a plan diagram schematically illustrating the positional relations among the silicon oxide film 312, the channel region 341, and some other components. The whole region of FIG. 6 is filled with the silicon nitride film 311. In FIG. 6, the source region 343, the drain region 342, and the channel region 341 therebetween are denoted by lines with arrows. The arrows represent the channel length directions and the directions perpendicular thereto are channel width directions.

As illustrated in the planar view of FIG. 6, the silicon oxide film 312 has a smaller area than the channel region 341 and the entire silicon oxide film 312 lies on (included in) the channel region 341. The entire left, right, upper, and lower ends (sides) of the silicon oxide film 312 lie on (included in) the channel region 341 in the planar view of FIG. 6. The left and right ends are the opposite ends in the channel length direction (horizontal direction) and the upper and lower ends are the opposite ends in the channel width direction (vertical direction).

The right end of the silicon oxide film 312 is the end facing the source electrode 306 (and the source region 343). The left end of the silicon oxide film 312 is the end facing the drain electrode 305 (and the drain region 342). The entire right end of the silicon oxide film 312 facing the source electrode 306 (and the source region 343) lies on the channel region 341. The entire left end of the silicon oxide film 312 facing the drain electrode 305 (and the drain region 342) lies on the channel region 341. At least a part of either the right end or the left end can lie outside (does not need to lie on) the channel region 341.

In the configuration example in FIG. 6, the distance (minimum distance) LR between the right end of the silicon oxide film 312 and an end of the source electrode 306 is equal to the distance (minimum distance) LL between the left end of the silicon oxide film 312 and an end of the drain electrode 305. In another configuration example, these distances can be different. The centroid of the silicon oxide film 312 coincides with the centroid of the channel region 341. In another configuration example, these centroids do not need to coincide. Although the silicon oxide film 312 in the example of FIGS. 5 and 6 has a shape of a cuboid, the shape of the silicon oxide film 312 is not limited specifically.

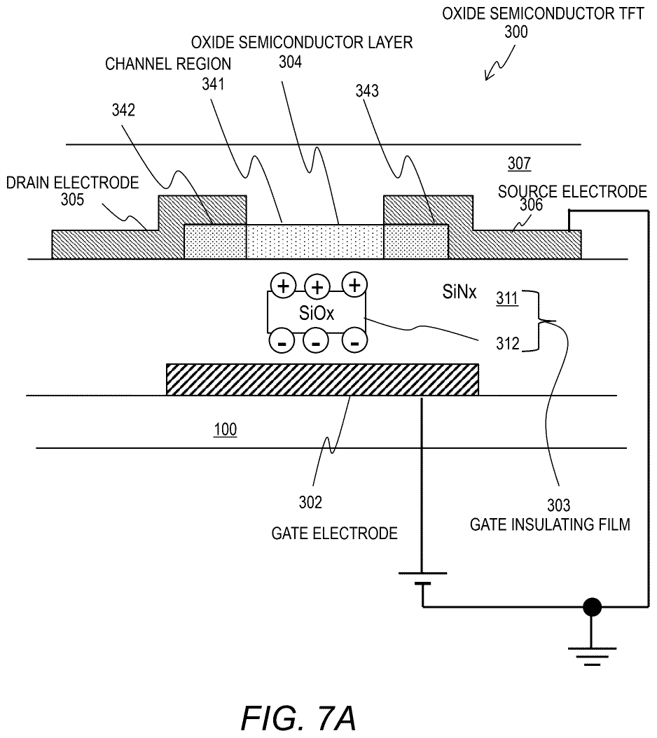

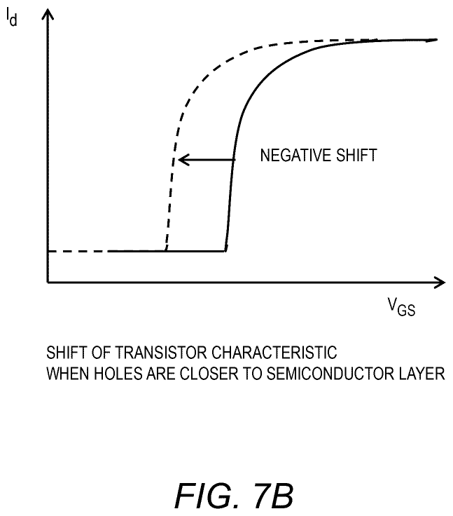

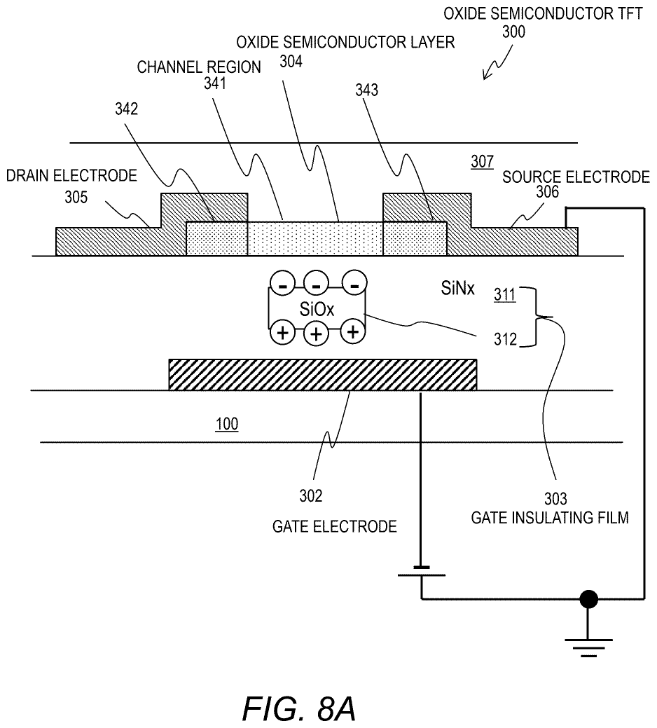

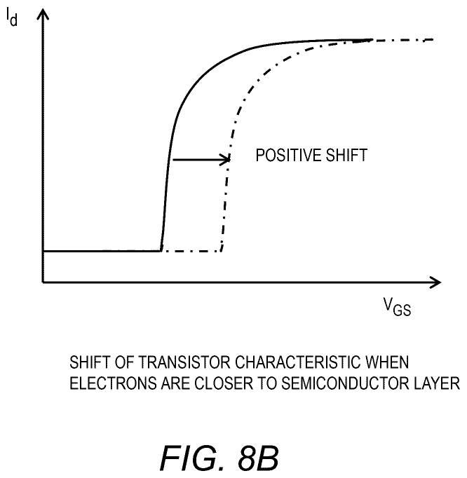

FIGS. 7A and 8A each schematically illustrate a charge state occurring when the oxide semiconductor TFT 300 in the embodiment illustrated in FIGS. 5 and 6 is supplied with a gate bias and irradiated with radioactive rays. FIGS. 7A and 8A each schematically illustrate a state of charges generated in response to irradiation with radioactive rays (e.g., X-rays of 500 Gy or more) when a voltage is being applied between the gate electrode 302 and the source electrode 306.

FIG. 7A illustrates a state where the gate electrode 302 is supplied with a positive voltage with respect to the potential of the source electrode 306. Electrons (−) and holes (+) are excited in the silicon oxide film 312 by the radioactive rays. The holes gather to the interface between the top face (the face facing the oxide semiconductor layer 304) of the silicon oxide film 312 and the silicon nitride film 311 and the electrons gather to the interface between the under face (the face facing the gate electrode 302) of the silicon oxide film 312 and the silicon nitride film 311 because of the electric field between the gate electrode 302 and the source electrode 306.

FIG. 8A illustrates a state where the gate electrode 302 is supplied with a negative voltage with respect to the potential of the source electrode 306. Electrons (−) and holes (+) are excited in the silicon oxide film 312 by the radioactive rays. The electrons gather to the interface between the top face (the face facing the oxide semiconductor layer 304) of the silicon oxide film 312 and the silicon nitride film 311 and the holes gather to the interface between the under face (the face facing the gate electrode 302) of the silicon oxide film 312 and the silicon nitride film 311 because of the electric field between the gate electrode 302 and the source electrode 306.

In each state of FIGS. 7A and 8A, the distance between the electrons and the oxide semiconductor layer 304 is different from the distance between the holes and the oxide semiconductor layer 304. Specifically, in the state of FIG. 7A, the distance between the holes and the oxide semiconductor layer 304 is shorter than the distance between the electrons and the oxide semiconductor layer 304. In the state of FIG. 8A, the distance between the electrons and the oxide semiconductor layer 304 is shorter than the distance between the holes and the oxide semiconductor layer 304.

In the state of FIG. 7A, the holes are gathered at a position closer to the oxide semiconductor layer 304 than the electrons and therefore, a positive field is generated on the interface of the oxide semiconductor layer 304 to shift the threshold voltage negatively. FIG. 7B is a graph schematically illustrating the negative shift of the threshold voltage. The horizontal axis represents the gate-source voltage and the vertical axis represents the drain current. In the state of FIG. 8A, the electrons are gathered at a position closer to the oxide semiconductor layer 304 than the holes and therefore, a negative field is generated on the interface of the oxide semiconductor layer 304 to shift the threshold voltage positively. FIG. 8B is a graph schematically illustrating the positive shift of the threshold voltage. The horizontal axis represents the gate-source voltage and the vertical axis represents the drain current.

The states of the charges in FIGS. 7A and 8A can be maintained after the radioactive ray irradiation and voltage application are stopped. The threshold voltage of the oxide semiconductor layer 304 can be controlled positively or negatively depending on the charge state of the oxide semiconductor layer 304. For effective control of the threshold voltage of the oxide semiconductor layer 304, the important is to generate a strong positive or negative field on the interface between the oxide semiconductor layer 304 and the silicon nitride film 311.

The electric field for the oxide semiconductor layer 304 is caused by the difference between the distance from electrons to the oxide semiconductor layer 304 and the distance from holes to the oxide semiconductor layer 304. As described with reference to FIGS. 5 and 6, the silicon oxide film 312 in an embodiment of this disclosure has a small area. This configuration attains a large difference in intensity between the electric field by electrons and the electric field by holes, so that the oxide semiconductor layer 304 can be provided with an effective electric field for controlling the threshold voltage. This phenomenon is explained in the following.

According to a theory of electromagnetics, the intensity of the electric field generated along the normal to a plane by a charge distributed on the plane depends on the distance from the plane more when the plane is smaller. This can be understood from the fact that the intensity of the electric field generated by a planar charge having an infinitely large area does not depend on the distance from the plane but the intensity of the electric field by a small planar charge that can be regarded as a point charge depends on z⁻², where z represents the distance from the plane.

Since a charge is distributed on the interface between the silicon oxide film 312 and the silicon nitride film 311, a planar charge having a small area can be generated by reducing the size of the silicon oxide film 312. As a result, the field generated by the charge close to the oxide semiconductor layer 304 and the field generated by the charge far from the oxide semiconductor layer 304 has a large difference in intensity. Accordingly, to shift the threshold voltage positively, the control should apply a voltage between the source and the gate so that the charge close to the oxide semiconductor layer will have the negative polarity and irradiates the TFT with high-energy light. Conversely, to shift the threshold voltage negatively, the control should apply a voltage between the source and the gate so that the charge close to the oxide semiconductor layer will have the positive polarity and irradiates the TFT with high-energy light.

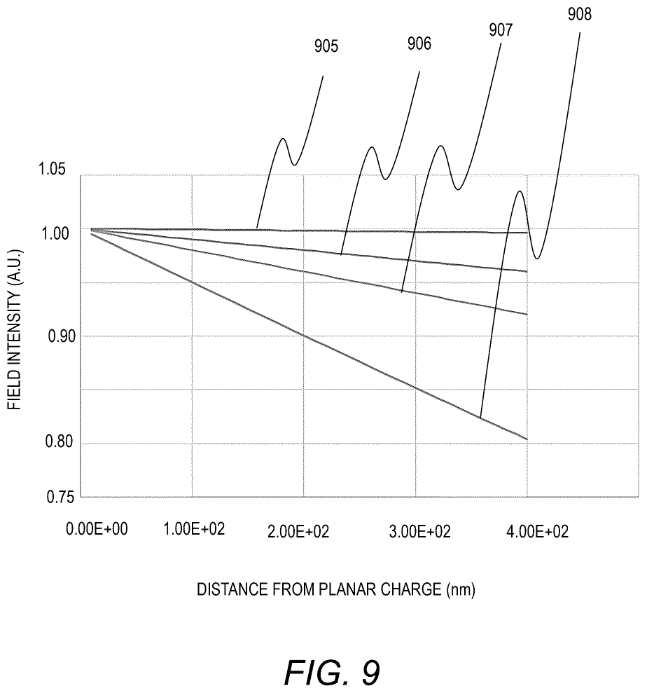

The effect of reducing the area of the silicon oxide film 312 is described with reference to FIG. 9. FIG. 9 provides a graph illustrating the relations between the intensity of electric fields generated by planar charges having different areas and the distance from the planar charges. Assuming that each of the planes has a circular shape and a constant charge density, the relations are based on theoretical calculation. The horizontal axis of the graph represents the distance (nm) from the planar charge and the vertical axis represents the field intensity (A.U.).

The line 905 represents the relation between the intensity of the electric field by a circular planar charge having a radius of 100 μm and the distance. The line 906 represents the relation between the intensity of the field by a circular planar charge having a radius of 10 μm and the distance. The line 907 represents the relation between the intensity of the field by a circular planar charge having a radius of 5 μm and the distance. The line 908 represents the relation between the intensity of the field by a circular planar charge having a radius of 2 μm and the distance.

As understood from the graph of FIG. 9, when a planar charge has a smaller area, the difference in distance from the planar charge generates a larger difference in field intensity. Assuming that the silicon oxide film 312 has a thickness of approximately 400 nm and the distance between the top face of the silicon oxide film 312 and the under face of the oxide semiconductor layer 304 is approximately 10 nm, the silicon oxide film 312 having a radius of 100 μm exhibits a small intensity difference between the field by electrons and the field by holes at the silicon oxide film 312. In contrast, the silicon oxide film 312 having a radius of 2 μm exhibits a large difference in intensity between the field by electrons and the fields by holes at the silicon oxide film 312 and therefore, the oxide semiconductor layer 304 can be provided with a stronger field by the charge near the oxide semiconductor layer.

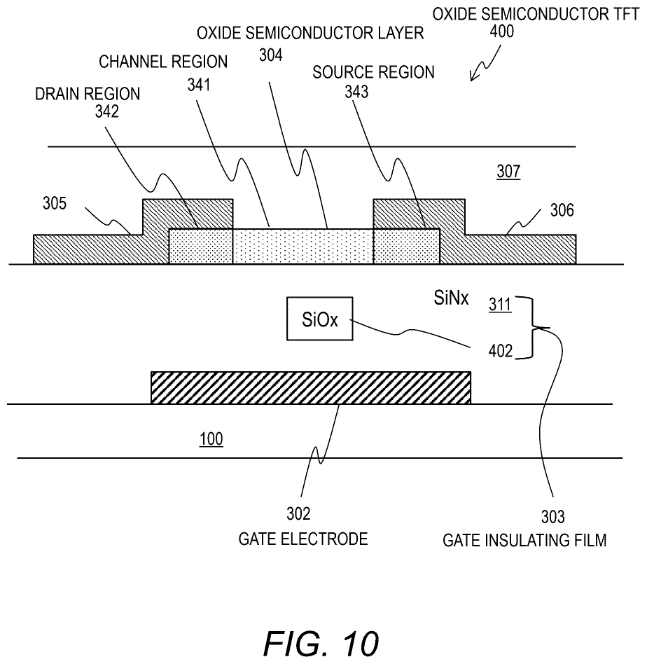

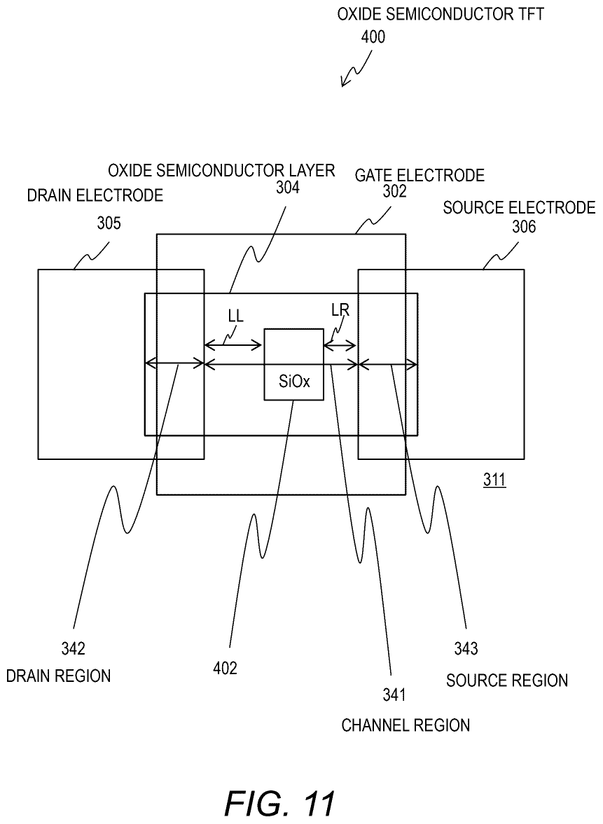

Hereinafter, the configurations of oxide semiconductor TFTs in some other embodiments of this disclosure are described. FIG. 10 is a cross-sectional diagram schematically illustrating the configuration of an oxide semiconductor TFT 400 in an embodiment of this disclosure. FIG. 11 is a plan diagram schematically illustrating the positional relations among the silicon oxide film 402, the channel region 341, and some other components in the oxide semiconductor TFT 400 illustrated in FIG. 10.

The following mainly describes differences from the configuration example in FIGS. 5 and 6. As to the components provided with the same reference signs as those for the components described with FIGS. 5 and 6, the description provided for the oxide semiconductor TFT 300 is applicable. Compared to the silicon oxide film 312 of the oxide semiconductor TFT 300, the silicon oxide film 402 is disposed closer to the source electrode 306 than the drain electrode 305.

With reference to FIG. 11, the distance (minimum distance) LR between the right end of the silicon oxide film 402 and an end of the source electrode 306 is shorter than the distance (minimum distance) LL between the left end of the silicon oxide film 402 and an end of the drain electrode 305. The distance (minimum distance) between the centroid of the silicon oxide film 402 and the end of the source electrode 306 is shorter than the distance (minimum distance) between the same centroid to the end of the drain electrode 305 in a planar view.

The silicon oxide film 402 has an island-like shape isolated within the silicon nitride film 311 and its entire region in the planar view is located within the channel region 341. In other words, the silicon oxide film 402 has a smaller area than the channel region 341 in the planar view. Each of the region between the silicon oxide film 402 and the oxide semiconductor layer 304 and the region between the silicon oxide film 402 and the gate electrode 302 is filled with a part of the silicon nitride film 311 as illustrated in FIG. 10.

The threshold voltage of the oxide semiconductor depends more on the potential of the region closer to the source electrode. Accordingly, the silicon oxide film 402 disposed closer to the source electrode 306 than the drain electrode 305 enables a larger threshold voltage shift.

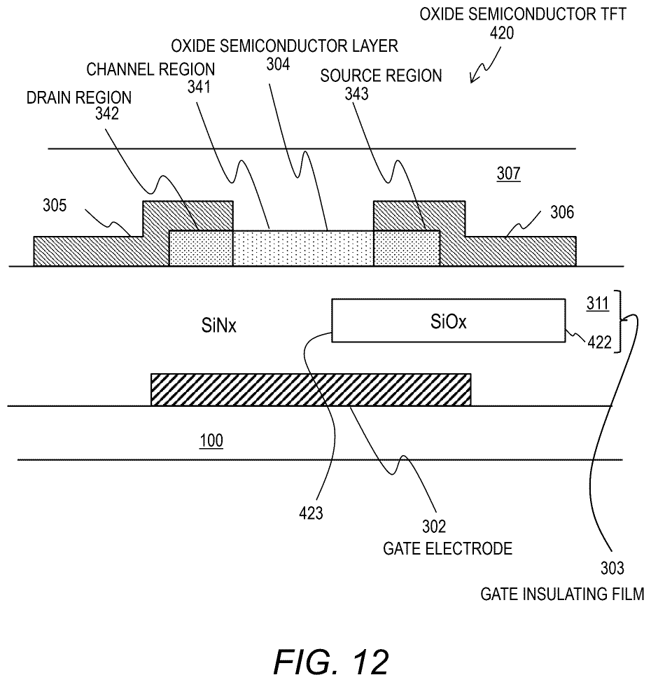

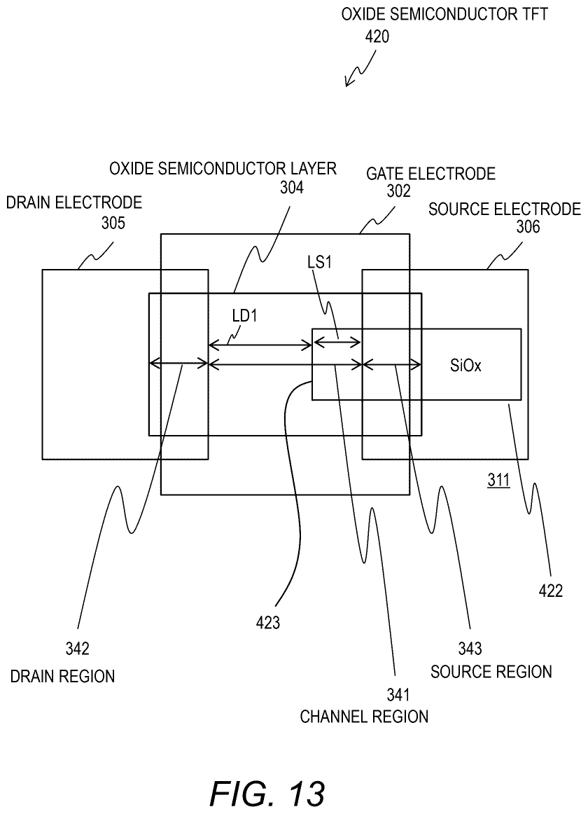

FIG. 12 is a cross-sectional diagram schematically illustrating the configuration of an oxide semiconductor TFT 420 in another embodiment of this disclosure. FIG. 13 is a plan diagram schematically illustrating the positional relations among the silicon oxide film 422, the channel region 341, and some other components in the oxide semiconductor TFT 420 illustrated in FIG. 12.

The following mainly describes differences from the configuration example in FIGS. 5 and 6. As to the components provided with the same reference signs as those for the components described with FIGS. 5 and 6, the description provided for the oxide semiconductor TFT 300 is applicable. Compared to the silicon oxide film 312 of the oxide semiconductor TFT 300, a part of the silicon oxide film 422 is located outside the channel region 341 in a planar view. Specifically, the source-side region of the silicon oxide film 422 does not overlap the channel region 341 in a planar view. The source-side region of the silicon oxide film 422 overlaps the source region 343 and/or the source electrode 306 in the planar view.

With reference to the planar view of FIG. 13, the drain-side end 423 of the silicon oxide film 422 faces the drain electrode 305. The entire drain-side end 423 lies on the channel region 341 in the planar view. The distance LS1 between the drain-side end 423 and an end of the source electrode 306 is shorter than the distance LD1 between the drain-side end 423 and an end of the drain electrode 305.

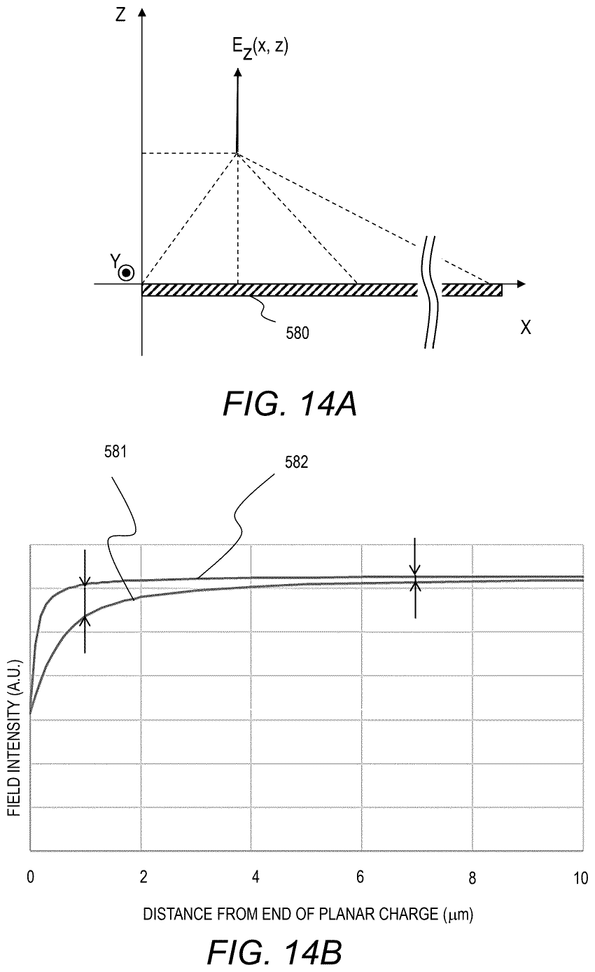

The disposition of the silicon oxide film 422 such that its drain-side end 423 is located closer to the source electrode 306 than the drain electrode 305 attains a larger threshold voltage shift. This effect is described with reference to FIGS. 14A and 14B.

FIG. 14A illustrates a planar charge 580 spreading infinitely in both positive and negative directions of the Y-axis and the positive direction along the X-axis. FIG. 14B indicates the intensity of the Z-axis component of the electric field generated by the planar charge 580 in FIG. 14A at different coordinates (x, z). The horizontal axis represents the distance along the X-axis (the value of the x-coordinate) from the end toward the center of the planar charge and the vertical axis represents the intensity of the Z-axis component of the electric field. The point 0 on the horizontal axis corresponds to the position of the end of the planar charge 580.

The curve 581 represents the variation in field intensity at the z-coordinate of 500 nm and the curve 582 represents the variation in field intensity at the z-coordinate of 10 nm. As understood from the comparison between the curves 581 and 582, the difference between field intensities at different z-coordinates is larger at a position closer to the end of the planar charge. The disposition of the silicon oxide film 422 such that its end 423 is located closer to the source electrode 306 than the drain electrode 305 generates a large difference in intensity between the electric fields by the electrons and holes vertically separated in the layering direction in the region of the oxide semiconductor layer close to the source electrode, enabling effective threshold voltage control.

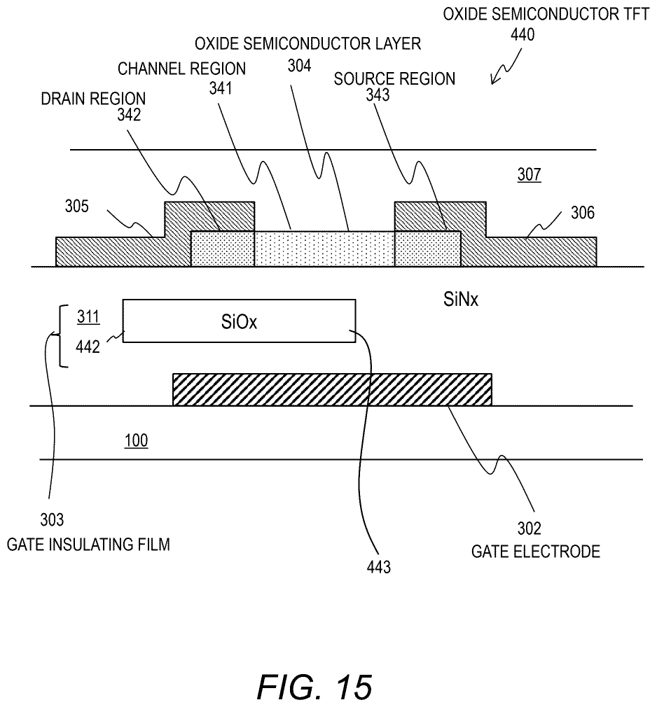

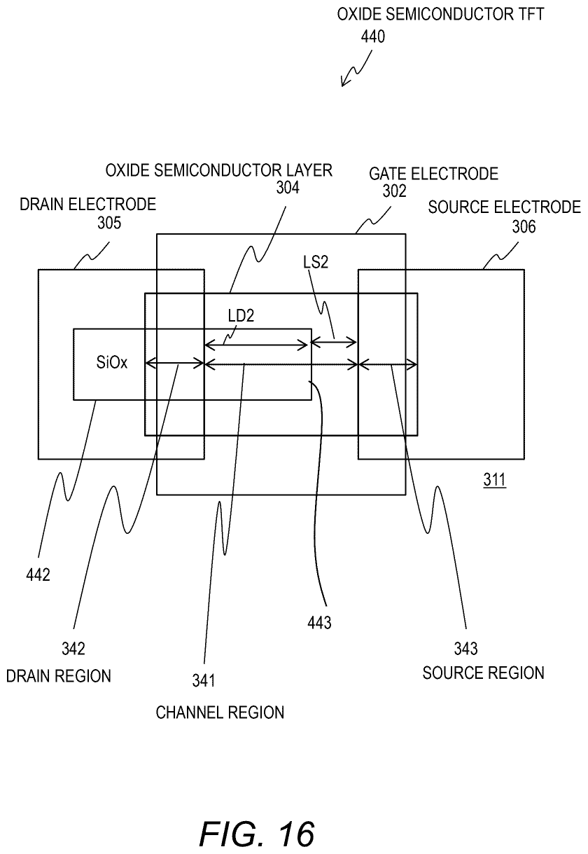

FIG. 15 is a cross-sectional diagram schematically illustrating the configuration of an oxide semiconductor TFT 440 in still another embodiment of this disclosure. FIG. 16 is a plan diagram schematically illustrating the positional relations among the silicon oxide film 442, the channel region 341, and some other components in the oxide semiconductor TFT 440 illustrated in FIG. 15.

The following mainly describes differences from the configuration example in FIGS. 5 and 6. As to the components provided with the same reference signs as those for the components described with FIGS. 5 and 6, the description provided for the oxide semiconductor TFT 300 is applicable. Compared to the silicon oxide film 312 of the oxide semiconductor TFT 300, a part of the silicon oxide film 442 is located outside the channel region 341 in a planar view. Specifically, the drain-side region of the silicon oxide film 442 does not overlap the channel region 341 in a planar view. The drain-side region of the silicon oxide film 442 overlaps the drain region 342 and/or the drain electrode 305 in the planar view.

With reference to the planar view of FIG. 16, the source-side end 443 of the silicon oxide film 442 faces the source electrode 306. The entire source-side end 443 lies on the channel region 341 in the planar view. The distance LS2 between the source-side end 443 and an end of the source electrode 306 is shorter than the distance LD2 between the source-side end 443 and an end of the drain electrode 305. As described with reference to FIGS. 14A and 14B, the disposition of the silicon oxide film 442 such that its source-side end 443 is located closer to the source electrode 306 than the drain electrode 305 attains a larger threshold voltage shift.

In the structure of an oxide semiconductor transistor described with reference to FIG. 13, the distance LS1 between the drain-side end 423 and the end of the source electrode 306 can be equal to or longer than the distance LD1 between the drain-side end 423 and the end of the drain electrode 305. In the structure of an oxide semiconductor transistor described with reference to FIG. 16, the distance LS2 between the source-side end 443 and the end of the source electrode 306 can also be equal to or longer than the distance LD2 between the source-side end 443 and the end of the drain electrode 305.

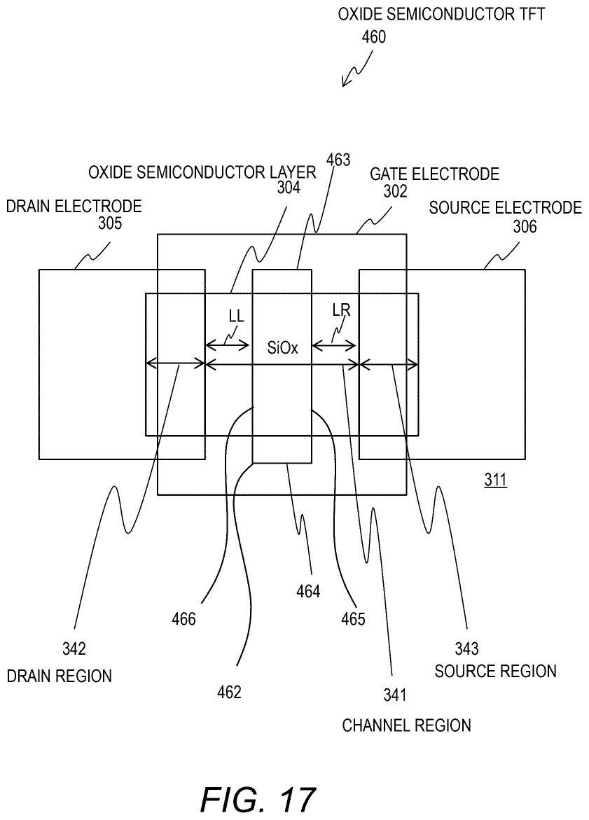

FIG. 17 is a plan diagram schematically illustrating the configuration of an oxide semiconductor TFT 460 in still another embodiment of this disclosure. Differences from the configuration example in FIG. 6 are mainly described. Parts of the silicon oxide film 462 do not lie on the channel region 341 and they are located outside the channel region 341 in the planar view. The both ends in the channel width direction of the silicon oxide film 462, or the upper end 463 and the lower end 464 in FIG. 17, are located outside the channel region 341 in the planar view.

Accordingly, a part of the source-side end 465 of the silicon oxide film 462 lies on the channel region 341 and the other parts lie outside the channel region 341. In similar, a part of the drain-side end 466 of the silicon oxide film 462 lies on the channel region 341 and the other parts lie outside the channel region 341. The threshold voltage of the oxide semiconductor TFT 460 can be effectively controlled, like those of the oxide semiconductor TFTs in the other embodiments.

Like in the oxide semiconductor TFT 300 described with FIGS. 5 and 6, each of the region between the silicon oxide film 462 and the oxide semiconductor layer 304 and the region between the silicon oxide film 462 and the gate electrode 302 is filled with a part of the silicon nitride film.

Although the both ends in the channel width direction of the silicon oxide film 462 are located outside the channel region 341, one of the ends can lie on the channel region 341 and the other one can lie outside the channel region 341 in a planar view. The configuration described with reference to FIG. 17, or the configuration in which an end in the channel width direction of the silicon oxide film is located outside the channel region 341 in a planar view, is applicable to the configuration examples described with reference to FIGS. 10 to 13, 15, and 16.

As described above, in the oxide semiconductor TFTs described with reference to FIGS. 5 to 17, at least a part of an end facing either the source electrode or the drain electrode lies on the channel region in a planar view.

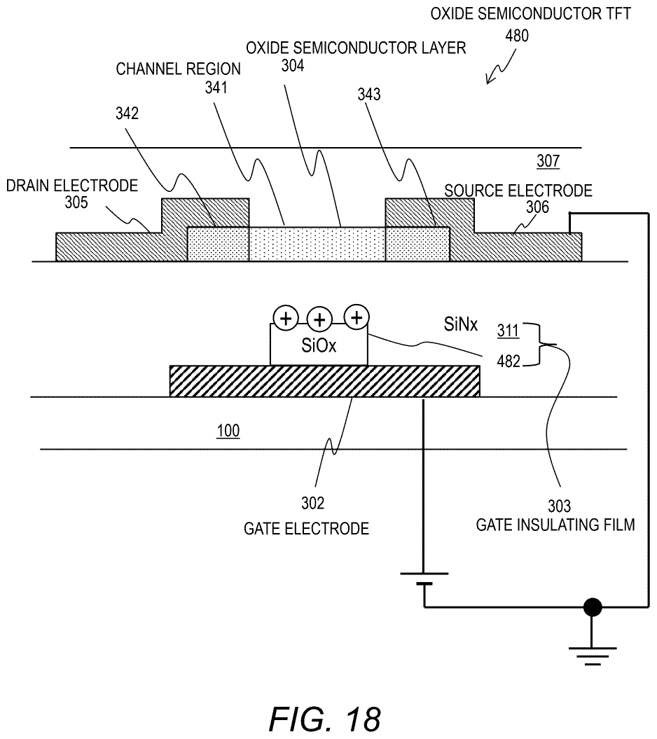

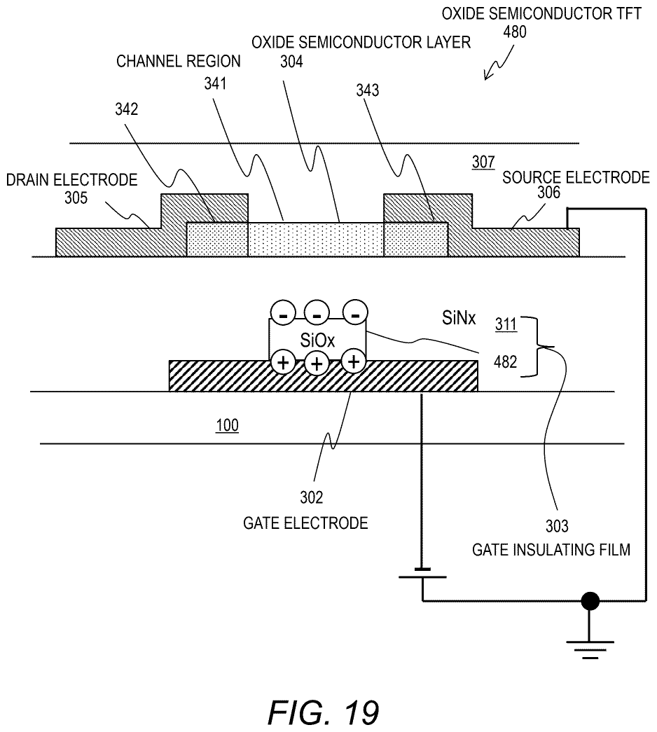

FIGS. 18 and 19 are cross-sectional diagrams schematically illustrating the configuration of an oxide semiconductor TFT 480 in still another embodiment of this disclosure. Compared to the oxide semiconductor TFT 300 described with reference to FIGS. 5 and 6, this oxide semiconductor TFT 480 is different in the position in the layering direction of the silicon oxide film and the same in the other components. Specifically, the silicon oxide film 482 is in direct contact and has an interface with the gate electrode 302.

FIGS. 18 and 19 each schematically illustrate a charge state occurring when the oxide semiconductor TFT 480 is supplied with a gate bias and irradiated with radioactive rays. FIG. 18 illustrates a state where the gate electrode 302 is supplied with a positive voltage with respect to the potential of the source electrode 306. FIG. 19 illustrates a state where the gate electrode 302 is supplied with a negative voltage with respect to the potential of the source electrode 306. In either state, the oxide semiconductor layer 304 can be supplied with an electric field by the charge trapped in the interface between the silicon nitride film 311 and the surface of the silicon oxide film 482 facing the oxide semiconductor layer 304. The silicon oxide film can also be in direct contact with the gate electrode in the oxide semiconductor TFTs described with reference to FIGS. 10 to 17.

In the oxide semiconductor TFTs described with reference to FIGS. 5 to 19, the metal oxide film in the gate insulating film can be made of a material different from silicon oxide. For example, aluminum oxide can be employed, instead of silicon oxide. Furthermore, the material of the insulating film exemplified by the silicon nitride film 311 is not specifically limited and for example, silicon oxynitride can be employed. In other examples, a layered structure of a silicon nitride film and a silicon oxynitride film or a plurality of silicon nitride films can replace the silicon nitride film 311.

For example, a lower layer of silicon nitride or silicon oxynitride can be provided between the metal oxide film and the bottom-gate electrode and an upper layer of silicon nitride or silicon oxynitride can be provided between the metal oxide film and the oxide semiconductor layer. The number of layers of the insulating film surrounding the metal oxide film is not limited specifically. The metal oxide film can also have a single-layer or multilayer structure.

The oxide semiconductor TFT in an embodiment of this disclosure can have a top-gate electrode, instead of the bottom-gate electrode described with reference to FIGS. 5 to 19. The gate insulating film between the top-gate electrode and the oxide semiconductor layer can have various structures, as descried with reference to FIGS. 5 to 19.

The oxide semiconductor TFT in another embodiment of this disclosure can have both of a top-gate electrode and a bottom-gate electrode. The top-gate insulating film between the top-gate electrode and the oxide semiconductor layer and the bottom-gate insulating film between the bottom-gate electrode and the oxide semiconductor layer can have the structure of one of the gate insulating films in the foregoing embodiments.

In the oxide semiconductor TFTs described with reference to FIGS. 5 to 19, the source electrode and the drain electrode are provided above (upper than) the oxide semiconductor layer. In another configuration example, the source electrode and the drain electrode can be provided below (lower than) the oxide semiconductor layer.

Hereinafter, some examples of the method of manufacturing an oxide semiconductor TFT, more specifically, the gate insulating film of the oxide semiconductor TFT, are described. The examples of the method to be described produce a gate insulating film having a structure such that an isolated silicon oxide film is embedded in a silicon nitride insulating film. The other components can be produced by widely known methods and therefore, description thereof is omitted herein. Forming, patterning, etching, and/or removing a film for each component can employ any of the widely known methods.

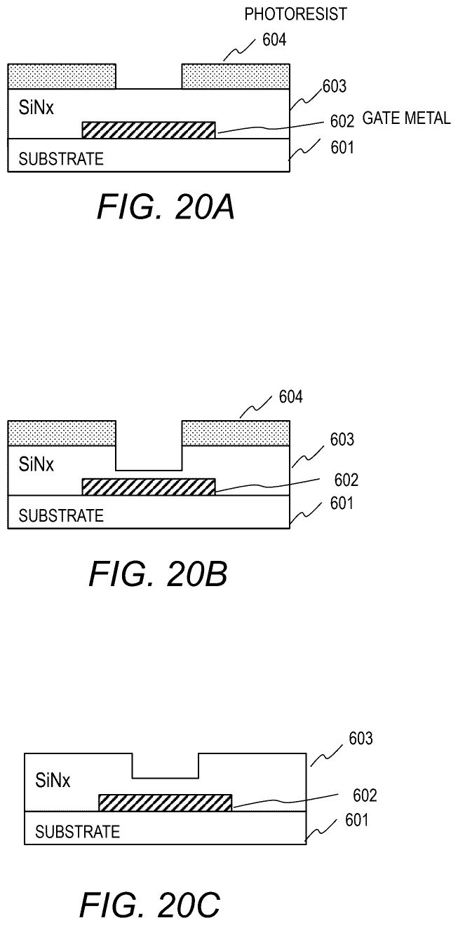

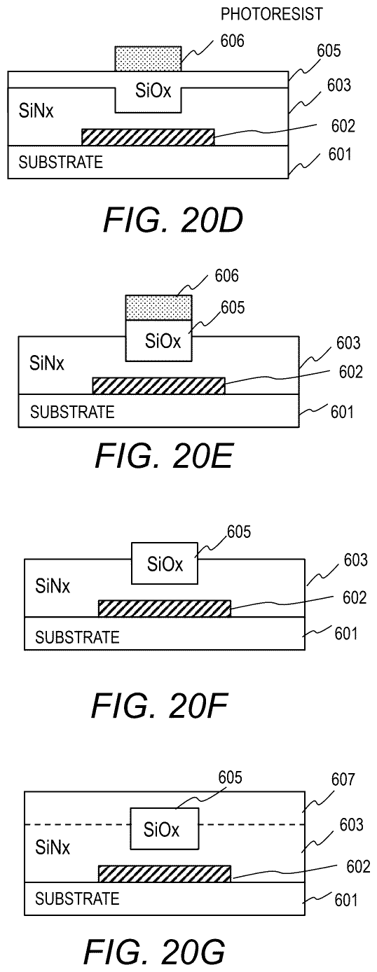

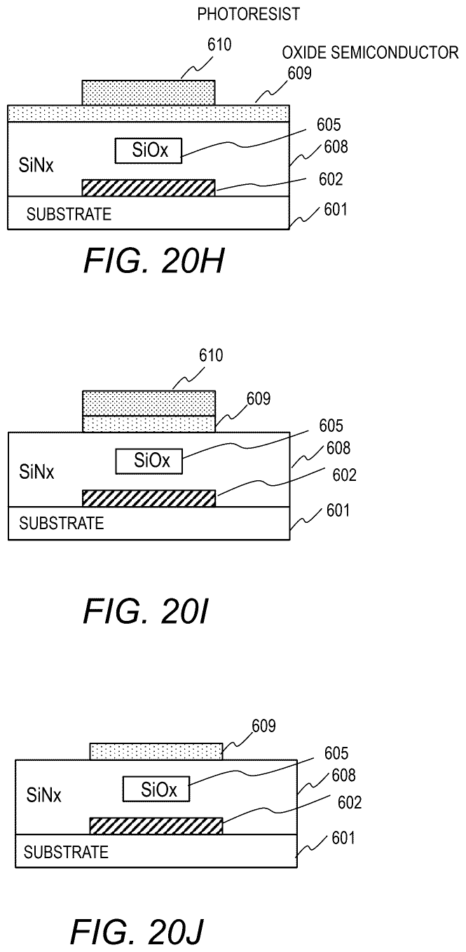

A first manufacturing method is described with reference to FIGS. 20A to 20J. With reference to FIG. 20A, the method deposits a gate metal film 602 on a substrate 601, patterns it, deposits a silicon nitride film 603 thereabove, and patterns a photoresist 604. Next, with reference to FIG. 20B, the method etches the silicon nitride film 603 in the opening of the photoresist 604 by a desired depth. Next, with reference to FIG. 20C, the method removes the photoresist 604.

Next, with reference to FIG. 20D, the method deposits a silicon oxide film 605 and patterns a photoresist 606. Next, with reference to FIG. 20E, the method etches the silicon oxide film 605 in the opening of the photoresist 606. Next, with reference to FIG. 20F, the method removes the photoresist 606. Next, with reference to FIG. 20G, the method deposits a silicon nitride film 607 above the silicon oxide film 605 in the entire region of the TFT.

Next, with reference to FIG. 20H, the method deposits an oxide semiconductor film 609 and patterns a photoresist 610. The layered structure of the silicon nitride film 603 and silicon nitride film 607 is denoted by a reference numeral 608. Next, with reference to FIG. 20I, the method etches the oxide semiconductor film 609. Next, with reference to FIG. 20J, the method removes the photoresist 610.

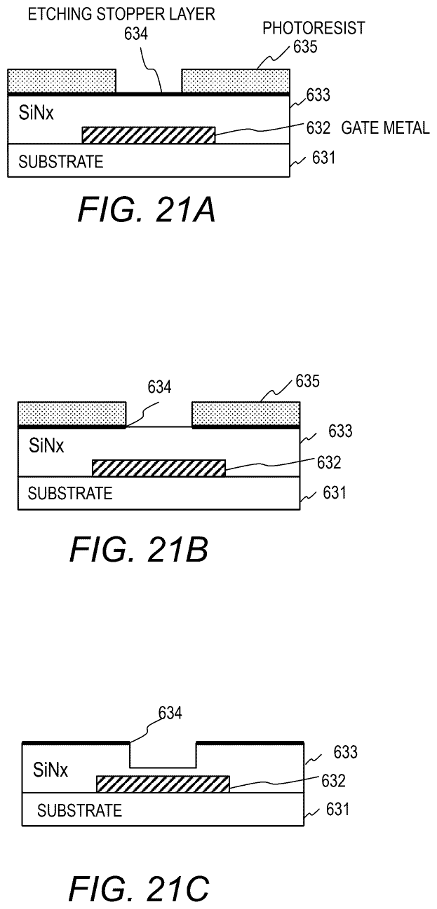

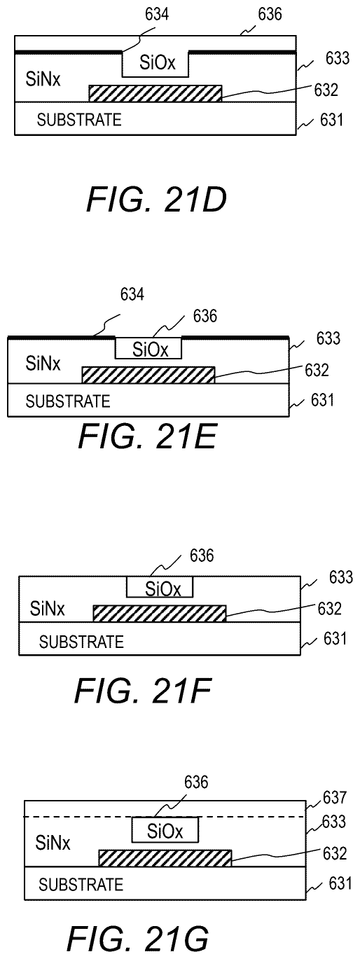

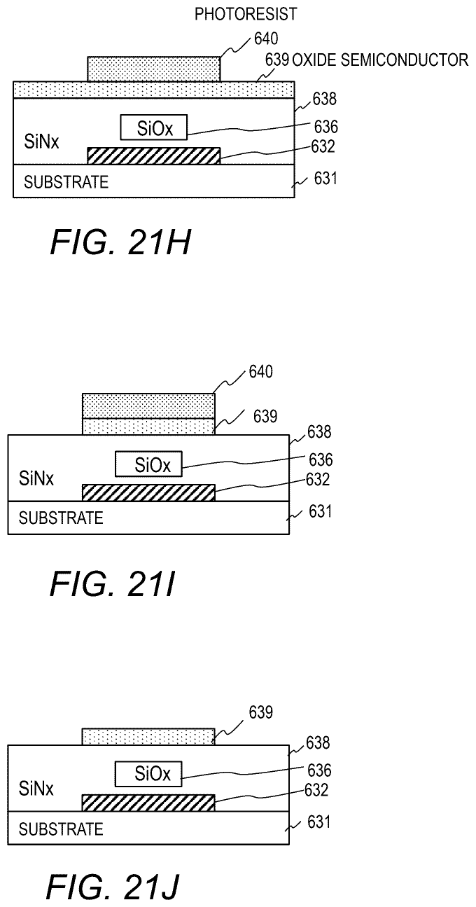

A second manufacturing method is described with reference to FIGS. 21A to 21J. This method is more complicated than the first method, but it improves the thickness uniformity of the gate insulating film. With reference to FIG. 21A, the method deposits a gate metal film 632 on a substrate 631, patterns it, deposits a silicon nitride film 633 and an etching stopper layer 634 thereabove, and patterns a photoresist 635.

Next, with reference to FIG. 21B, the method etches the etching stopper layer 634. Next, with reference to FIG. 21C, the method etches the silicon nitride film 633 using the etching stopper layer 634 as a mask. Next, with reference to FIG. 21D, the method deposits a silicon oxide film 636 above the entire etching stopper layer 634.

Next, with reference to FIG. 21E, the method etches the silicon oxide film 636 until the silicon oxide upper than the etching stopper layer 634 is removed. In this process, the etching stopper layer 634 prevents over etching of the silicon nitride film 633. Next, with reference to FIG. 21F, the method removes the etching stopper layer 634. Next, with reference to FIG. 21G, the method deposits a silicon nitride film 637 above the silicon oxide film 636 in the entire region of the TFT.

Next, with reference to FIG. 21H, the layered structure of the silicon nitride film 633 and silicon nitride film 637 is denoted by a reference numeral 638. The method deposits an oxide semiconductor film 639 above the silicon nitride film 638, deposits a photoresist 640 thereabove, and patterns the photoresist 640. Next, with reference to FIG. 21I, the method etches the oxide semiconductor film 639. Next, with reference to FIG. 21J, the method removes the photoresist 640.

As set forth above, embodiments of this disclosure have been described; however, this disclosure is not limited to the foregoing embodiments. Those skilled in the art can easily modify, add, or convert each element in the foregoing embodiments within the scope of this disclosure. A part of the configuration of one embodiment can be replaced with a configuration of another embodiment or a configuration of an embodiment can be incorporated into a configuration of another embodiment.

1. An oxide semiconductor thin-film transistor comprising:
a gate electrode;
a source electrode;
a drain electrode;
an oxide semiconductor layer connected to the source electrode and the drain electrode; and
a gate insulating film between the gate electrode and the oxide semiconductor layer in a layering direction;
wherein the oxide semiconductor layer includes a channel region,
wherein the gate insulating film includes:
a metal oxide film; and
a first insulating film made of silicon nitride and/or silicon oxynitride,
wherein a part of the first insulating film is disposed between the metal oxide film and the oxide semiconductor layer, and
wherein at least a part of a first end of the metal oxide film lies on the channel region and faces either one of the source electrode and the drain electrode in a planar view.

2. The oxide semiconductor thin-film transistor according to claim 1, wherein the minimum distance between the first end and the source electrode is shorter than the minimum distance between the first end and the drain electrode.

3. The oxide semiconductor thin-film transistor according to claim 2,
wherein the first end faces the source electrode in a planar view,
wherein the metal oxide film includes a second end facing the drain electrode in the planar view, and
wherein at least a part of the second end lies on the channel region in the planar view.

4. The oxide semiconductor thin-film transistor according to claim 1,
wherein the metal oxide film has an island-like shape,
wherein the metal oxide film has a smaller area than the channel region in a planar view, and
wherein the entire metal oxide film lies on the channel region in the planar view.

5. The oxide semiconductor thin-film transistor according to claim 1, wherein the entire surface of the metal oxide film is surrounded by the first insulating film.

6. The oxide semiconductor thin-film transistor according to claim 5, wherein the minimum distance between the centroid of the metal oxide film and the source electrode in a planar view is shorter than the minimum distance between the centroid of the metal oxide film and the drain electrode in the planar view.

7. The oxide semiconductor thin-film transistor according to claim 1, wherein the metal oxide film has an interface with the gate electrode.

8. The oxide semiconductor thin-film transistor according to claim 1, wherein the metal oxide film is made of silicon oxide and the first insulating film is made of silicon nitride.
